(19) United States
(12) Patent Application Publication
(10) Pub. No.: US 2006/0054932 A1
(43) Pub. Date: Mar. 16, 2006

(54) Semiconductor device, high-frequency amplifier and personal digital assistant

(75) Inventors: Takahiro Yokoyama, Hyogo (JP); Hirotaka Miyamoto, Toyama (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd.

(21) Appl. No.: 11/224,043

(22) Filed: Sep. 13, 2005

(30) Foreign Application Priority Data
Sep. 13, 2004 (JP) 2004-264985

(51) Int. Cl. H01L 31/109; H01L 29/739

(52) U.S. Cl. 257/197; 257/198

(57) ABSTRACT

A semiconductor device includes a GaAs substrate, a sub-collector layer provided on the GaAs substrate, a collector layer provided on part of the sub-collector layer, a base layer (first semiconductor layer) provided on the collector layer, a second emitter layer (second semiconductor layer) provided on part of the base layer located in an intrinsic base region, and a first emitter layer provided on the second emitter layer.

### BACKGROUND OF THE INVENTION

The present invention relates to the miniaturization of semiconductor devices, high-frequency amplifiers and personal digital assistants including a heterojunction bipolar transistor.

GaAs based compound semiconductor is widely used as a high-frequency component of, for example, a cellular phone and the like because of its excellent high-frequency characteristics. Especially, unlike known GaAs field-effect transistors (FETs), GaAs heterojunction bipolar transistors (which will be hereinafter referred to as “HBTs”) can be operated with only a positive-voltage power supply source and, therefore, demands for GaAs heterojunction bipolar transistors as high-frequency transistors have been increased.

GaAs has a lower heat conductivity than that of Si. Thus, in an HBT using GaAs, a heterogeneous operation is caused by self-heating in many cases. In general, as shown in FIG. 18, HBTs are used in the manner where a plurality of unit HBTs 100 are connected in parallel. FIG. 18 is a cross-sectional view illustrating the structure of a known semiconductor device. In each of the unit HBTs 100, when applied power is increased, the temperature of each unit HBT 100 is increased by self-heating. When the temperature of each unit HBT 100 is increased, a turn ON voltage is reduced and a collector current is increased. Accordingly, the amount of heat generated by self-heating is further increased and the temperature of each unit HBT 100 is further increased. In this manner, a positive feedback exists between a collector current and the temperature of each unit HBT 100. Normally, it is expected that due to the positive feedback, the collector current is rapidly increased and the unit HBTs 100 are broken down. However, actually, as the unique phenomenon of HBTs, the collector current is rapidly reduced. The minute difference in resistance value among respective thermal resistances of the unit HBTs 100 is a factor of this phenomenon. Because of the difference in thermal resistance value, the temperature increases differently among the unit HBTs 100. As a result, more current flows in only one or a few of the unit HBTs 100 which have the highest temperature and less current flows in the rest of the unit HBTs 100. Accordingly, the collector current as a whole is rapidly reduced. In general, the rapid drop in the collector current is called current collapse and is known as a phenomenon that occurs in a GaAs HBT in many cases.

To reduce the current collapse phenomenon, it is general to add a ballast resistance to a base of each of the unit HBTs. However, in such a case, the following problem arises. In many cases, the base is used as a high-frequency input terminal and, if a ballast resistance is added to the base in such a structure, a gain is reduced. As a result, a power efficiency is reduced (for example, see W. Liu et. al, “The Use of Base Ballasting to Prevent the Collapse of Current Gain in AlGaAs/GaAs Heterojunction Bipolar Transistors,” IEEE Electron Devices, vol. 43, p. 245, 1996).

To cope with the problem, there have been proposed two methods. FIGS. 19 and 20 are circuit diagrams illustrating a configuration for preventing the reduction in power efficiency when a ballast resistance is added to a base in a known device. As shown in FIG. 19, according to the first method, a capacitor 129 is provided for each unit HBT so as to be parallel to a base ballast resistance 113 and connected to the unit HBT and a high-frequency input is bypassed (for example, see U.S. Pat. No. 5,321,279 and Japanese Laid-Open Publication No. 2004-111941).

In the second method, as shown in FIG. 20, a DC input terminal 115 and a RF input terminal 116 are provided in each unit HBT and a base ballast resistance 113 and a capacitor are connected to the DC input terminal 115 and the RF input terminal 116, respectively (for example, see U.S. Pat. No. 5,629,648). More specifically, the base ballast resistance 113 is connected between the DC input terminal 115 and a base of a unit HBT 125. On the other hand, the capacitor 129 is connected between the RF input terminal 116 and the base of the unit HBT 125. With this structure, a RF input signal is input to the base of the unit HBT 125 without passing through the base ballast resistance 113. Therefore, a gain is not reduced while the current collapse phenomenon is reduced due to the base ballast resistance, and consequently, the intrinsic characteristic of HBTs is realized.

However, to increase a gain in the first method, a capacitance value of the capacitor 129 provided in parallel to the base ballast resistance 113 has to be sufficiently large. As a result, a larger chip area is required.

On the other hand, according to the second method, DC and RF are separately input and therefore a DC input interconnect and a RF input interconnect have to be separately provided. Also, the capacitor 129 is provided for each unit HBT to be connected thereto. Therefore, a large chip area is required.

### SUMMARY OF THE INVENTION

It is an object of the present invention to provide a semiconductor device and a high-frequency amplifier which allow reduction in the current collapse phenomenon while suppressing increase in ch ip area.

According to the present invention, to achieve the miniaturization of a chip, a capacitor is provided in a transistor.

Specifically, a semiconductor device according to one embodiment of the present invention includes a first semiconductor layer including an intrinsic base region and an external base region; a second semiconductor region formed on the intrinsic base region so as to serve as an emitter region or a collector region; a capacitive film formed on part of the external base region; an electrode provided on the capacitive film; and a base electrode provided on other part of the external base region than the part of the external base region on which the capacitive film is provided.

### BRIEF DESCRIPTION OF THE DRAWINGS

FIG. 1 is a view illustrating a basic example of a high-frequency semiconductor device according to a first embodiment of the present invention.

FIG. 2 is a view illustrating a modified example of the semiconductor device of the first embodiment.

FIG. 3 is a view illustrating a modified example of the semiconductor device of the first embodiment.

FIG. 4 is a view illustrating a basic example of the semiconductor device of a second embodiment of the present invention.

FIG. 5 is a view illustrating a modified example of the semiconductor device of the second embodiment.

FIG. 6 is a view illustrating a modified example of the semiconductor device of the second embodiment.

FIG. 7 is a view illustrating a basic example of a high-frequency semiconductor device according to a third embodiment of the present invention.

FIG. 8 is a view illustrating a modified example of the semiconductor device of the third embodiment.

FIG. 9 is a view illustrating a modified example of the semiconductor device of the third embodiment.

FIG. 10A is a circuit diagram illustrating a high-frequency amplifier according to a fourth embodiment of the present invention, FIG. 10B is a view illustrating a semiconductor device of the fourth embodiment in which unit HBTs are connected in parallel, and FIG. 10C is a circuit diagram illustrating an equivalent circuit of the structure of FIG. 10B.

FIG. 11A is a circuit diagram illustrating a modified example of the high-frequency amplifier of the fourth embodiment, FIG. 11B is a view illustrating the semiconductor device of the fourth embodiment in which unit HBTs are connected in parallel, and FIG. 11C is a circuit diagram illustrating an equivalent circuit of the structure of FIG. 11B.

FIG. 12 is a view illustrating a basic example of a high-frequency semiconductor device according to a fifth embodiment of the present invention.

FIG. 13 is a view illustrating a modified example of the high-frequency semiconductor device of the fifth embodiment.

FIG. 14A is a circuit diagram illustrating a high-frequency amplifier according to a sixth embodiment of the present invention, FIG. 14B is a view illustrating a semiconductor device according to the sixth embodiment in which unit HBTs are connected in parallel, and FIG. 14C is a circuit diagram illustrating an equivalent circuit of the structure of FIG. 14B.

FIG. 15A is a circuit diagram illustrating a radio frequency front-end section of a personal digital assistant according to a seventh embodiment, and FIG. 15B is a circuit diagram illustrating the configuration of the transmission amplifier 44 of FIG. 15A.

FIG. 16A is a view illustrating a semiconductor device of the seventh embodiment in which unit HBTs are connected in parallel, and FIG. 16B is a circuit diagram illustrating an equivalent circuit of the structure of FIG. 16A.

FIGS. 17A and 17B are cross-sectional views illustrating an exemplary structure of a collector-up HBT according to the present invention.

FIG. 18 is a cross-sectional view illustrating the structure of a known semiconductor device.

FIG. 19 is a circuit diagram illustrating a configuration for preventing the reduction in power efficiency when a ballast resistance is added to a base in a known device.

FIG. 20 is a circuit diagram illustrating another configuration for preventing the reduction in power efficiency when a ballast resistance is added to a base in the known device.

### DESCRIPTION OF THE PREFERRED EMBODIMENTS

### First Embodiment

Hereinafter, the structure of a semiconductor device according to a the first embodiment of the present invention will be described with reference to the accompanying drawings.

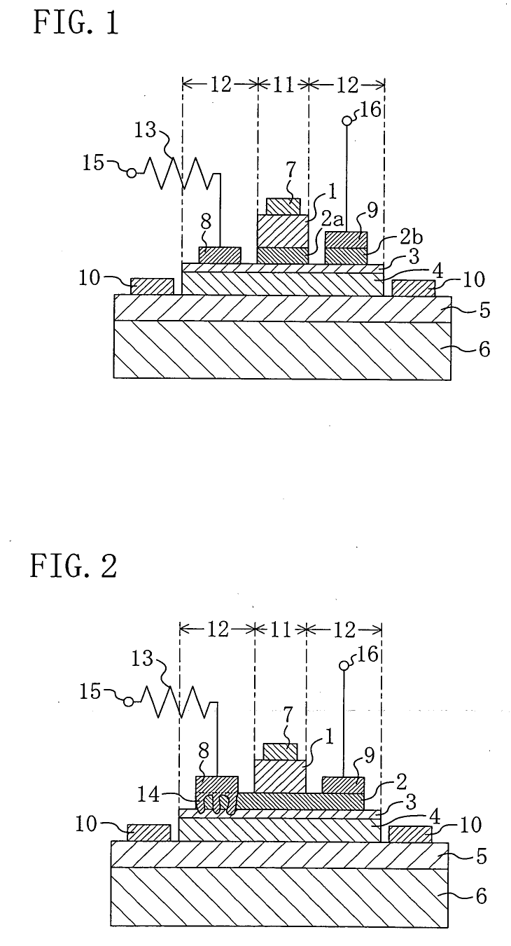

FIG. 1 is a view illustrating a basic example of a high-frequency semiconductor device according to the first embodiment of the present invention. In FIG. 1, an HBT formed on a GaAs substrate by epitaxial growth is illustrated as an example.

As shown in FIG. 1, the semiconductor device of this embodiment includes a GaAs substrate 6, a sub-collector layer 5 formed of n⁺-GaAs on the GaAs substrate 6 having an impurity concentration of 5×10¹⁸ cm⁻³ and a thickness of a 600 nm, a collector layer 4 formed of n⁻-GaAs on part of the sub-collector layer 5 and having an impurity concentration of 1×10¹⁶ cm⁻³ and a thickness of 800 nm, a base layer (first semiconductor layer) 3 formed of p-GaAs on the collector layer 4 and having an impurity concentration of 4×10¹⁹ cm⁻³ and a thickness of 80 nm, a second emitter layer (second semiconductor layer) 2a formed of n-In_{0.5}Ga_{0.5}P on part of the base layer 3 which is an intrinsic base region 11 and having an impurity concentration of 3×10¹⁷ cm⁻³ and a thickness of 30 nm, a second emitter layer (second semiconductor layer) 2b formed of n-In_{0.5}Ga_{0.5}P on part of the base layer 3 which is an external base region 12 and having an impurity concentration of 3×10¹⁷ cm⁻³ and a thickness of 30 nm, and a first emitter layer 1 formed of n⁺-InₓGa_{y}P (0≦x≦0.5, 0.5≦y≦1, x+y=1) on the second emitter layer 2a and having an impurity concentration of 3×10¹⁸ to 2×10¹⁹ cm⁻³ and a thickness of 200 nm. In this case, an emitter electrode 7 is provided on the first emitter layer 1, a base electrode 8 is provided on the part of the base layer 3 which is the external base region 12 so as to be separated from the second emitter layer 2a and the first emitter layer 1. A capacitive upper electrode 9 is provided on the second emitter layer 2b. A collector electrode 10 is provided on the sub-collector layer 5.

The semiconductor device of FIG. 1 is formed using resist masks by a conventional fabrication method of semiconductor devices such as wet etching, dry etching and electrode deposition. As shown in FIG. 1, the intrinsic base region 11 is a region of the base layer 3 in which an emitter current or a collector current flows and the external base region 12 is a region of the base layer 3 excluding the part thereof in which an emitter current or a collector current flows. The external base region 12 surrounds the intrinsic base region 11.

The region comprising a capacitive upper electrode 9, the second emitter layer 2b, and the base layer 3 acts as a capacitor for the following reason. With the base layer 3 formed of p-GaAs and the second emitter layer 2b formed of n-In_{0.5}Ga_{0.5}P, a pn junction is formed between the two layers and a junction capacitance is generated at the pnjunction. The p-type doping concentration of the base layer 3 (4×10¹⁹ cm⁻³) is two orders of magnitudes higher than the n-type doping concentration (3×10¹⁷ cm⁻³) of the second emitter layer 2 and the second emitter layer 2b has a small thickness, i.e., a thickness of 30 nm. Thus, the second emitter layer 2b is completely depleted by a built-in voltage (Vbi) of the pn junction. As a result, the capacitive upper electrode 9, the second emitter layer 2b and the base layer 3 function as a capacitor.

A base ballast resistance 13 is externally provided so that one end of the base ballast resistance 13 is connected to the base electrode 8. The other end of the base ballast resistance 13 serves as a DC input terminal 15. On the other hand, the capacitive upper electrode 9 serves as a RF input terminal 16.

According to this embodiment, the base electrode 8 and the capacitive upper electrode 9 are formed in the unit HBT and a basic circuit in which a DC input and a RF input are separately provided can be formed in a simple manner. By adopting above configuration, the current collapse phenomenon can be suppressed due to the base ballast resistance 13. Also, a RF input signal is input into the HBT without passing through the base ballast resistance 13. Therefore, a high gain and high efficiency can be achieved. In general, a metal thin film resistance such as NiCr, a semiconductor resistance using a semiconductor layer, or the like is used as the base ballast resistance 13.

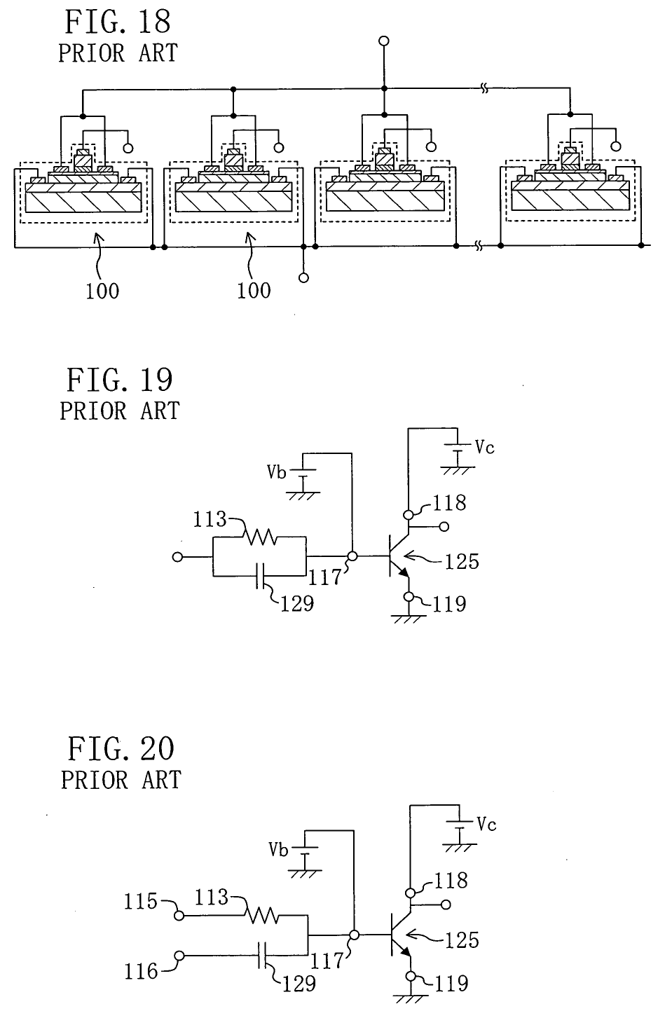

A capacitor in the known HBTs of FIGS. 18 and 19 has a M-I-M structure. A SiN film of about 200 nm deposited by plasma CVD is used for an insulation film (I). When the SiN film has a thickness of 200 nm, a capacitance value per 1 μm² is 3.1×10⁻¹⁶ (F/μm²). To increase a capacitance value per unit area, the thickness of the SiN film should be less than 200 nm. However, if the SiN film is formed so as to have a thickness of 200 nm or less, variation in film thickness is increased due to the possible limit of the thickness controllability of the deposition apparatus. Moreover, if a foreign substance such as a dust exits in a base electrode, a hole can be generated from where the foreign substance exists in the SiN film, thereby causing leakage current and a short circuit. That is, in the known capacitor, it is difficult to increase a capacitance value per unit area to a level exceeding the above-describe value.

On the other hand, in the capacitor of this embodiment, the n-In_{0.5}Ga_{0.5}P layer (second emitter layer 2b) having a thickness of 30 nm corresponds to the insulation film (I) in the M-I-M structure. The dielectric constant of In_{0.5}Ga_{0.5}P is about 11.9, which is 1.7 times larger than the dielectric constant of the SiN film, i.e., about 7.0. Furthermore, In_{0.5}Ga_{0.5}P is formed by epitaxial growth and, therefore, even if a film thickness is 200 nm or less, a hole or a leakage path is rarely generated and a leakage current is not caused. As a result, the capacitance value per 1 μm² becomes as high as 35.1×10⁻¹⁵ (F/μm²). This is about 11.3 times larger than that of a known M-I-M capacitance using a SiN film of 200 nm. Therefore, a high density capacitor with no leakage current can be realized easily.

In order to achieve desired high-frequency characteristics, a capacitor of about 0.3 pF is usually incorporated in the unit HBT (see U.S. Pat. No. 5,629,648). In the known capacitor using the SiN film, an area of about 970 μm² is required to achieve 0.3 pF. In contrast to that, a capacitance value of 0.3 pF can be achieved with an area of only about 86 μm² in this embodiment. A unit HBT of 20 μm to 30 μm length is usually used for the HBTs. In this case, for example, an area of 86 μm² can be obtained by setting the width of the capacitive upper electrode 9 and the length of the unit HBT to be 4.3 μm and 20 μm, respectively, or to be 2.9 μm and 30 μm, respectively. A width of 4.3 um or 2.9 um is small enough for incorporating the capacitive upper electrode 9 into the unit HBT itself. Accordingly, in this embodiment, unlike the known device, the capacitor does not have to be externally provided but can be incorporated in the unit HBT. Therefore, a chip area can be largely reduced.

In the structure of FIG. 1, the second emitter layer 2b provided in the intrinsic base region 11 and the second emitter layer 2a provided in the external base region 12 are separately provided. However, the second emitter layers 2a and 2b do not have to be separated but, as shown in FIG. 2, a single second emitter layer 2 may be provided. FIG. 2 is a view illustrating a modified example of the semiconductor device of the first embodiment. Even when the second emitter layer 2 is provided as shown in FIG. 2, part of the second emitter layer 2 located over the external base region 12 is completely depleted by the heavily doped p-type base layer 3 and does not exhibit conductivity. Therefore, the emitter electrode 7 and the capacitive upper electrode 9 are not short-circuited.

Moreover, in the structure of FIG. 1, the base electrode 8 is formed on the p-type base layer 3. However, as shown in FIG. 2, the base electrode 8 may be formed on the second emitter layer 2. In such a case, for example, the base electrode 8 is formed so as to have a multilayer structure of Pt/Ti/Pt/Au and is subjected to heat treatment at a temperature of 300° C. so that an alloy region 14 is formed in part of the second emitter layer 2 located under the base electrode 8. As a result, a metal-semiconductor contact comprising the base layer 3 and the base electrode 8 becomes ohmic contact.

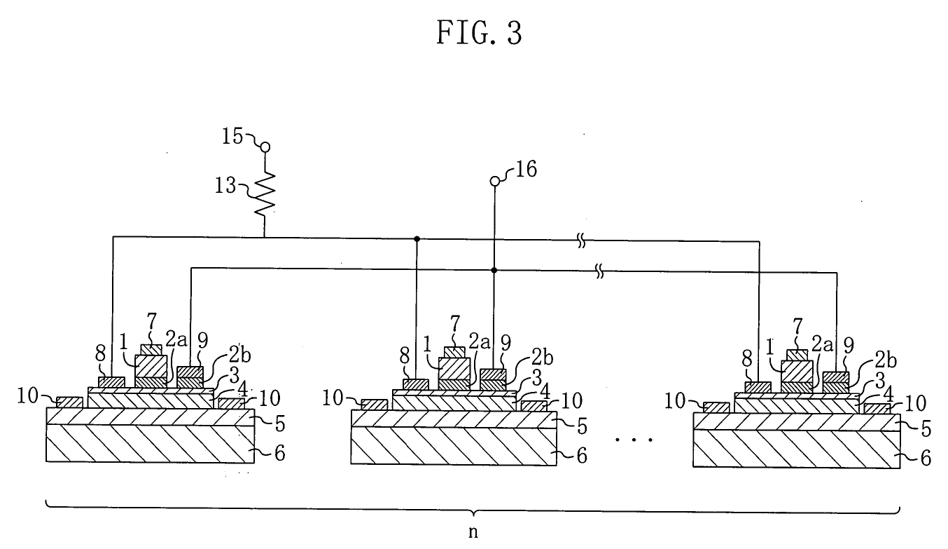

In FIGS. 1 and 2, the structure in which a single base ballast resistance 13 is connected to each single unit HBT has been described. However, as shown in FIG. 3, the structure in which a single base ballast resistance 13 is provided for n (n=2, 3, . . . ) unit HBTs may be used. FIG. 3 is a view illustrating a modified example of the semiconductor device of the first embodiment. With the structure of FIG. 3, conditions for fabricating a HBT can be also adjusted as follows. For example, n should be small (n=2-4) when the current collapse is large. If n is smaller, the feedback effect of ballast resistance becomes more significant for each unit HBT, and consequently, the current collapse decreases. Therefore, a value of n can be modified depending on the degree of the current collapse phenomenon, and the current collapse is suppressed effectively, even though the above-described configuration including a reduced number of base ballasts is adopted in the circuit.

### Second Embodiment

Hereinafter, the structure of a high-frequency semiconductor device according to a second embodiment of the present invention will be described with reference to the accompanying drawings.

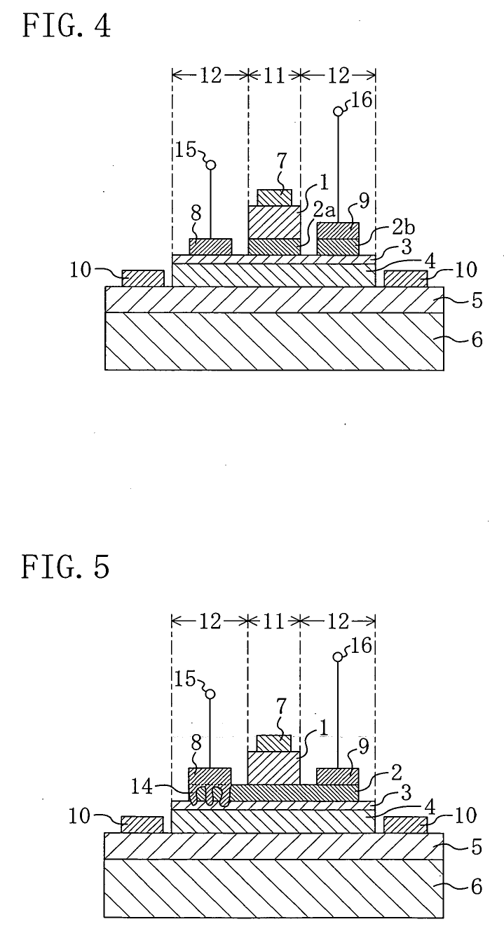

FIG. 4 is a view illustrating a basic example of the semiconductor device of the second embodiment. The semiconductor device of FIG. 4 has the same structure as the structure of FIG. 1 except that a base electrode 8 itself serves as a DC input terminal 15. Therefore, the detail description thereof will be omitted.

FIG. 5 is a view illustrating a modified example of the semiconductor device of the second embodiment. In this embodiment, as the semiconductor device of FIG. 5, a single emitter layer 2 may be formed so as to lie astride the intrinsic base region 11 and the external base region 12. Moreover, a base electrode 8 may be formed on the second emitter layer 2 so as to be electrically connected to a base layer 3 through an alloy region 14. The above-described members are configured in the manner described in the first embodiment and therefore the detail description thereof will be omitted.

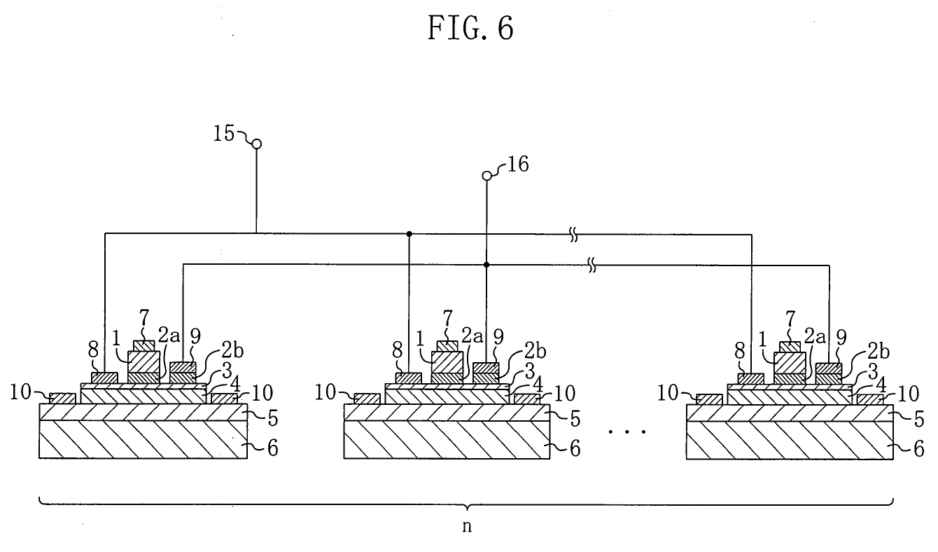

FIG. 6 is a view illustrating a modified example of the semiconductor device of the second embodiment. In this embodiment, as the semiconductor device of FIG. 6, unit HBTs of FIG. 4 or 5 may be connected in parallel. Even with this structure, conditions for fabricating an HBT can be also adjusted depending on the degree of the current collapse phenomenon in the same manner as that described in the first embodiment.

In this embodiment, as in the first embodiment, a capacitor does not have to be externally provided but can be incorporated in a unit HBT. Thus, a chip area can be largely reduced. Moreover, a RF input terminal 16 is a separate terminal from the DC input terminal 15 and a RF input signal is input into the unit HBT without passing through the base electrode 8. As described above, even when the base internal resistance is high, a high gain and high efficiency can be achieved.

### Third Embodiment

Hereinafter, the structure of a high-frequency semiconductor device according to a third embodiment of the present invention will be described with reference to the accompanying drawings.

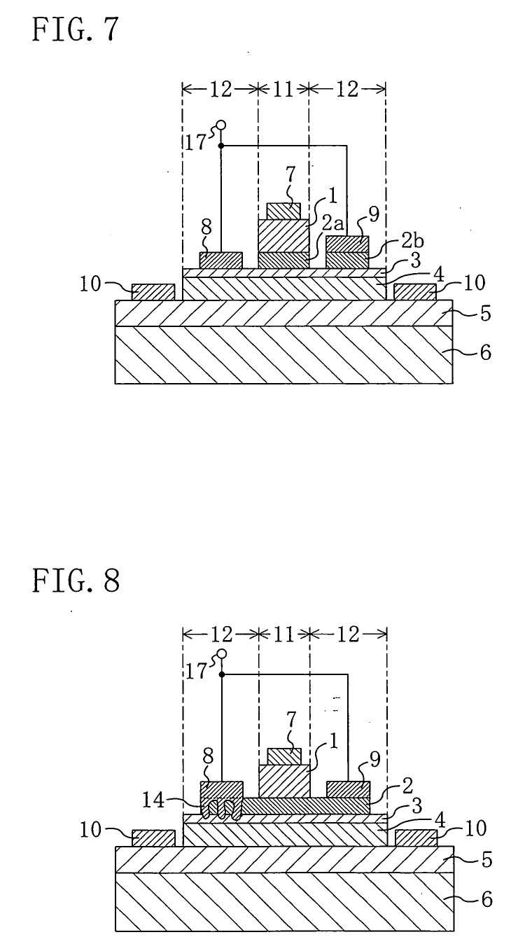

FIG. 7 is a view illustrating a basic example of a high-frequency semiconductor device according to the third embodiment. In the semiconductor device of FIG. 7, a base electrode 8 and a capacitive upper electrode 9 are electrically connected to each other to serve as a DC/RF common input terminal 17. Except for that, the structure of the semiconductor device of FIG. 7 is the same as the structure shown in FIG. 1 and therefore the detail description thereof will be omitted.

FIG. 8 is a view illustrating a modified example of the semiconductor device of the third embodiment. In this embodiment, as in the semiconductor device of FIG. 8, a single emitter layer 2 may be formed so as to lie astride an intrinsic base region 11 and an external base region 12. Moreover, the base electrode 8 may be formed on the second emitter layer 2 so as to be electrically connected to a base layer 3 through an alloy region 14. The above-described members are configured in the manner described in the first embodiment and therefore the detail description thereof will be omitted.

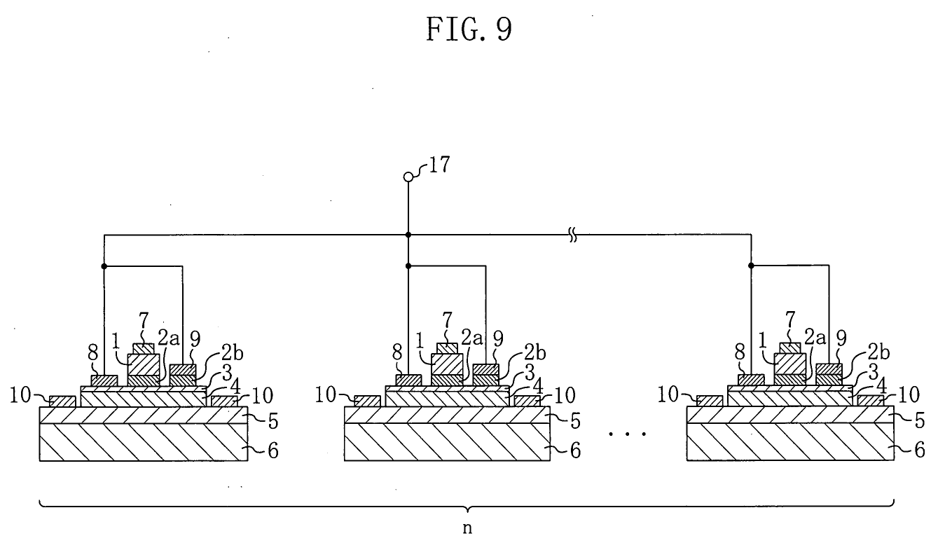

FIG. 9 is a view illustrating another modified example of the semiconductor device of the third embodiment. In this embodiment, as the semiconductor device of FIG. 9, unit HBTs of FIG. 7 or 8 may be connected in parallel. Even with this structure, conditions for fabricating a HBT can be also adjusted depending on the degree of the current collapse phenomenon in the same manner as that described in the first embodiment.

In this embodiment, a capacitor does not have to be externally provided but can be incorporated in the unit HBT. Therefore, a chip area can be largely reduced.

### Fourth Embodiment

Hereinafter, the structure of a high-frequency amplifier according to a fourth embodiment of the present invention will be described with reference to the accompanying drawings.

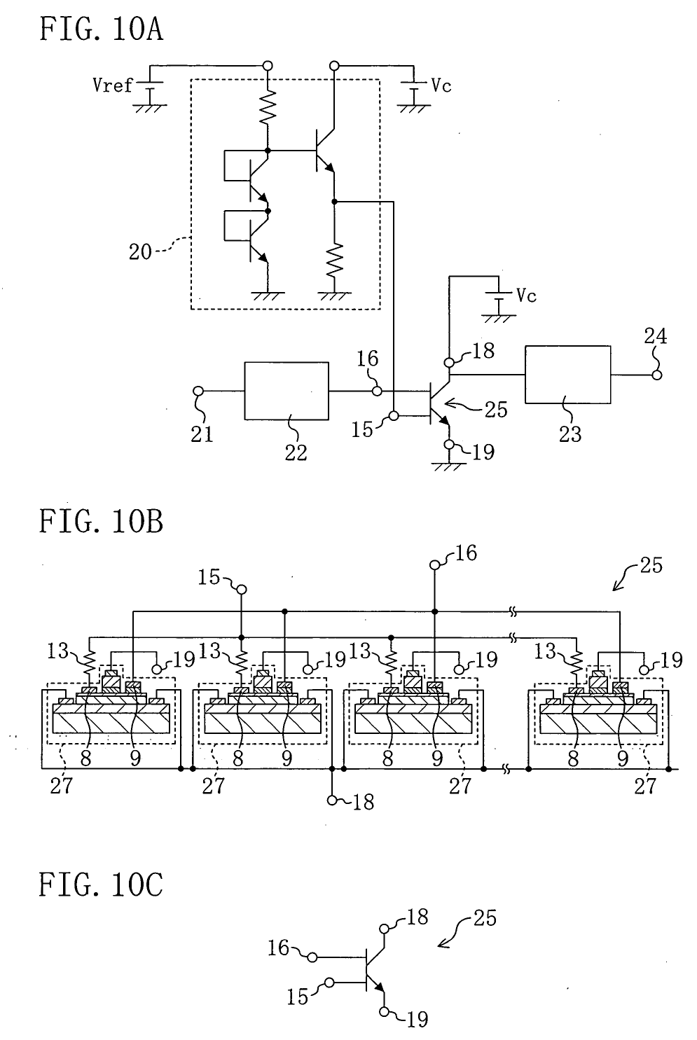

FIG. 10A is a circuit diagram illustrating the high-frequency amplifier of the fourth embodiment. In FIG. 10A, a grounded emitter single-stage amplifier is illustrated as an example.

As shown in FIG. 10A, in the high-frequency amplifier of this embodiment, an emitter of an HBT 25 is grounded, a DC input (base) of the HBT 25 is connected to a bias circuit 20 via a DC input terminal 15. Thus, a base voltage or a base current of the HBT 25 is controlled. In order to realize desired high-frequency characteristics of the HBT 25, an input matching circuit 22 and an output matching circuit 23 are connected to an input terminal 21 of the HBT 25 and an output terminal 24, respectively.

In this embodiment, as the HBT 25, for example, unit HBTs of FIG. 1 or 2 connected in parallel are used. FIG. 10B is a view illustrating a semiconductor device of the fourth embodiment in which unit HBTs are connected in parallel. As shown in FIG. 10B, a base ballast resistance 13 is connected to a base electrode 8 of each of unit HBTs 27. FIG. 10C is a circuit diagram illustrating an equivalent circuit of the structure of FIG. 10B.

In the high-frequency amplifier of this embodiment, the base ballast resistance 13 is provided in each of the unit HBTs 27. Thus, the current collapse phenomenon can be suppressed. Also, a RF input signal is input into each of the unit HBTs 27 without passing through the base ballast resistance 13. Therefore, a high gain and high efficiency can be achieved.

In this embodiment, unlike the known device, a capacitor does not have to be externally provided but can be incorporated in each of unit HBTs 27. Thus, a chip area can be largely reduced, so that the high-frequency amplifier can be fabricated at low cost.

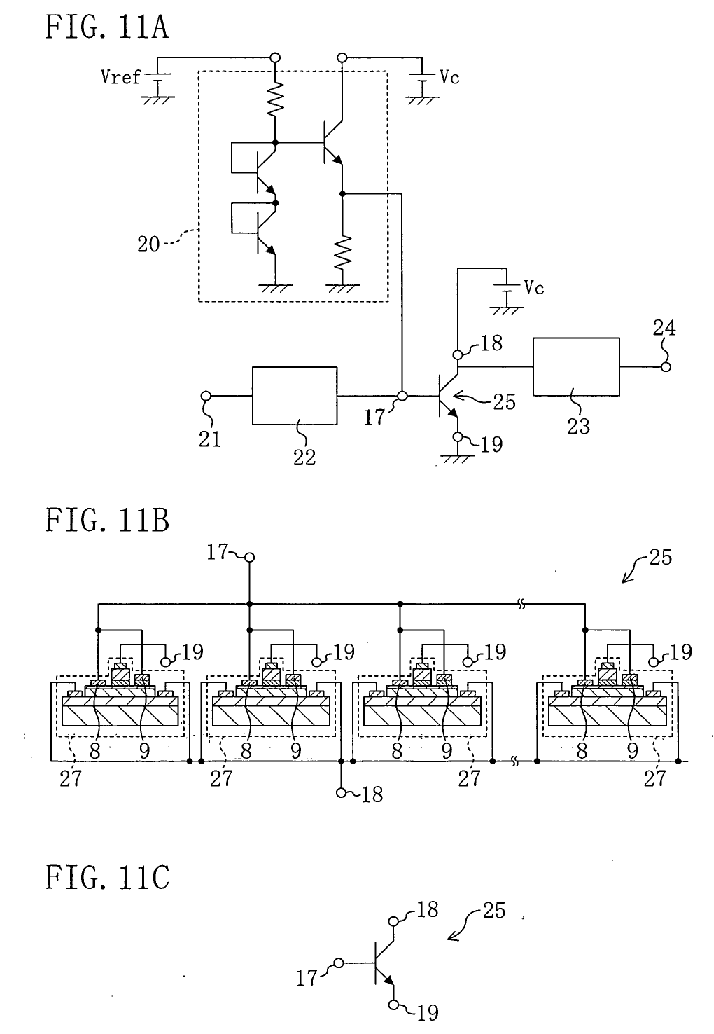

In the FIG. 10B, the base ballast resistance 13 is connected to each of the unit HBTs 27. However, as shown in FIG. 3, a single base ballast resistance may be provided for n unit HBTs 27 so as to be connected thereto or, as shown in FIGS. 6 and 9, the structure in which no base ballast resistance is connected to HBTs may be used. When the HBTs of FIG. 9 are used, a circuit in FIG. 9 is re-arranged in the manner shown in FIG. 11B, thereby forming an amplifier shown in FIG. 11A. FIG. 11A is a circuit diagram illustrating a modified example of the high-frequency amplifier of the fourth embodiment, FIG. 11B is a view illustrating the semiconductor device of the fourth embodiment in which unit HBTs are connected in parallel, and FIG. 11C is a circuit diagram illustrating an equivalent circuit of the structure of FIG. 11B, which corresponds to the HBT 25 of FIG. 11A.

Here, in each of FIGS. 10A through 10C and FIGS. 11A through 11C, description has been made using the single-stage amplifier as an example. However, in this embodiment, an amplifier having some other circuit configuration, for example, a multi-stage amplifier can be used.

### Fifth Embodiment

Hereinafter, the structure of a high-frequency semiconductor device according to a fifth embodiment of the present invention will be described with reference to the accompanying drawings.

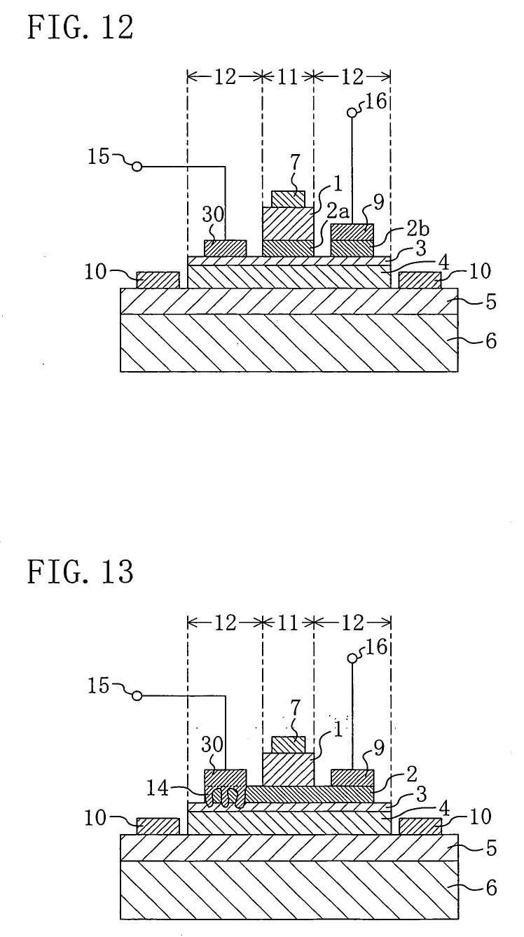

FIG. 12 is a view illustrating a basic example of a high-frequency semiconductor device according to the fifth embodiment. Except that a base electrode 30 also functions as a resistance, the semiconductor device of FIG. 12 has the same structure as that of FIG. 1 and therefore the description thereof will be omitted. To make the base electrode 30 also function as a resistance, the contact resistance between the base electrode 30 and the base layer 3 can be increased, for example, to about 1×10⁻⁵ Ωcm⁻², or the internal resistance of the base electrode 30 can be increased by using as the base electrode 30 a material having a very low conductivity so that the base electrode 30 itself functions as a base ballast resistance.

FIG. 13 is a view illustrating a modified example of the high-frequency semiconductor device of the fifth embodiment. In this embodiment, as the semiconductor device of FIG. 13, a single second emitter layer 2 may be formed so as to lie astride the intrinsic base region 11 and the external base regions 12. In other cases, the base electrode 8 may be formed on the second emitter layer 2 so as to be electrically connected to the base layer 3 through the alloy region 14. Note that the above-described members are configured in the manner described in the first embodiment and therefore the detail description thereof will be omitted.

In this embodiment, a high gain and high efficiency can be achieved while the current collapse phenomenon is suppressed. Also, a capacitor does not have to be externally provided but can be incorporated in each of unit HBTs 27. Therefore, a chip area can be largely reduced.

### Sixth Embodiment

Hereinafter, the structure of a high-frequency amplifier according to a sixth embodiment of the present invention will be described with reference to the accompanying drawings.

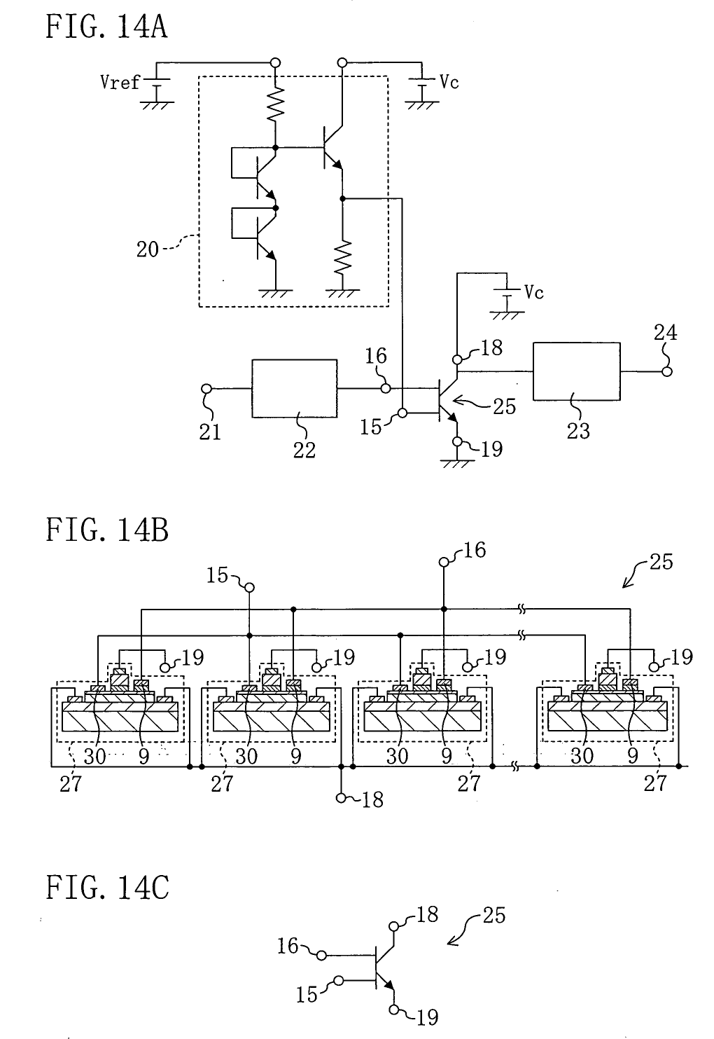

FIG. 14A is a circuit diagram illustrating the high-frequency amplifier of the sixth embodiment. In FIG. 14A, a grounded emitter single-stage amplifier is illustrated as an example.

As shown in FIG. 14A, in the high-frequency amplifier of this embodiment, an emitter of an HBT 25 is grounded, a DC input terminal of the HBT 25 is connected to a bias circuit 20 via a DC input terminal 15. Thus, a base voltage or a base current of the HBT 25 is controlled. In order to realize desired high-frequency characteristics of the HBT 25, an input matching circuit 22 and an output matching circuit 23 are connected to an input terminal 21 of the HBT 25 and an output terminal 24, respectively.

In this embodiment, as the HBT 25, for example, a structure shown in FIG. 14B in which the unit HBTs of FIG. 12 or 13 are connected in parallel is used. FIG. 14B is a view illustrating a semiconductor device according to the sixth embodiment in which unit HBTs are connected in parallel. In FIG. 14B, a base electrode 30 of each of the unit HBTs 27 also functions as a resistance. FIG. 14C is a circuit diagram illustrating an equivalent circuit of the structure of FIG. 14B.

In the high-frequency amplifier of this embodiment, the base electrode 30 in each of the unit HBTs 27 functions as a ballast resistance, so that the current collapse phenomenon can be suppressed. Also, a RF input. signal is input into each of the unit HBTs 27 without passing through the base electrode 30. Therefore, a high gain and high efficiency can be achieved.

In this embodiment, unlike the known device, a capacitor does not have to be externally provided but can be incorporated in each of unit HBTs 27. Therefore, a chip area can be largely reduced, so that the high-frequency amplifier can be fabricated at low cost.

Here, in each of FIGS. 14A through 14C, description has been made using the single-stage amplifier as an example. However, in this embodiment, an amplifier having some other circuit configuration, for example, a multi-stage amplifier can be used.

### Seventh Embodiment

Hereinafter, a personal digital assistant according to a seventh embodiment of the present invention will be described with reference to the accompanying drawings. The personal digital assistant of this embodiment includes one of the high-frequency semiconductor devices of the first, second, third, and fifth embodiments or one of the high-frequency amplifiers of the fourth and sixth embodiments.

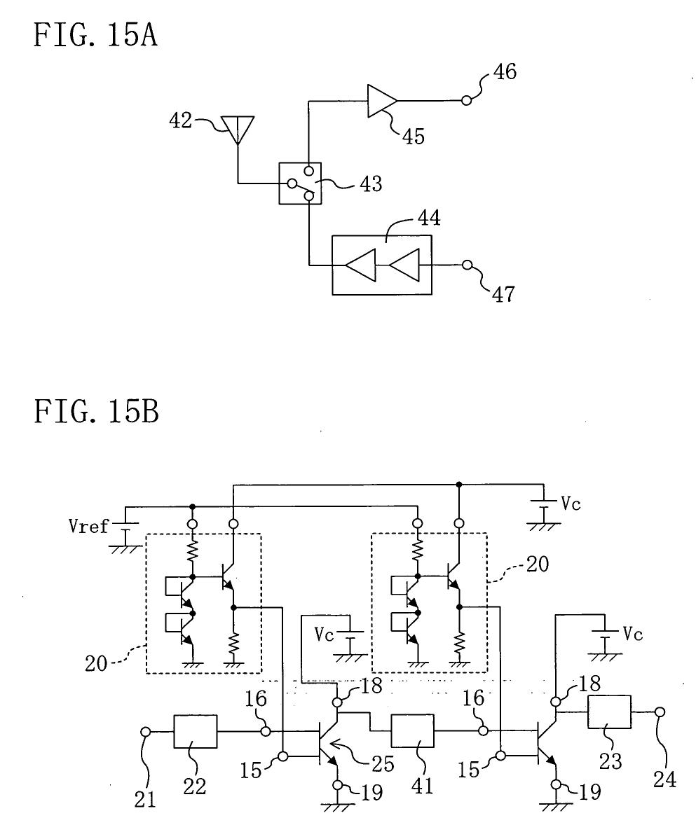

FIG. 15A is a circuit diagram illustrating a radio frequency (RF) front-end section of the personal digital assistant (including a cellular phone) of the seventh embodiment. As shown in FIG. 15A, the RF front-end section of this embodiment includes a transmission amplifier 44 for amplifying a signal to be transmitted, a low noise amplifier 45 for amplifying a received signal, an antenna switch 43 and an antenna 42. The antenna switch 43 controls a signal path. The transmitted signal path is from an amplifier 44 to an antenna 42, and the received signal path is from an antenna 42 to a low noise amplifier 45. The low noise amplifier 45 is connected to a down-converter (not shown) via a terminal 46. The transmission amplifier 44 is connected to an up-converter (not shown) via a terminal 47. The down-converter converts a RF signal into an IF signal and the up-converter converts an IF signal into a RF signal.

FIG. 15B is a circuit diagram illustrating the configuration of the transmission amplifier 44 of FIG. 15A. In FIG. 15B, the configuration of a grounded emitter two-stage amplifier is shown as an example. In FIG. 15B, two high-frequency amplifiers of FIG. 14A are connected to each other in a two-stage connection. An emitter of an HBT 25 is grounded and a DC input terminal of the HBT 25 is connected to a bias circuit 20 via a DC input terminal 15 so as to control a base voltage or a base current of the HBT 25. In order to realize desired high-frequency characteristics of the HBT 25, an input matching circuit 22 and an output matching circuit 23 are connected to an input terminal 21 of the HBT 25 and an output terminal 24, respectively.

In this embodiment, as the HBT 25, for example, a structure shown in FIG. 16A in which the unit HBTs of FIG. 12 or 13 are connected in parallel is used. FIG. 16A is a view illustrating a semiconductor device of the seventh embodiment in which unit HBTs are connected in parallel. In FIG. 16A, a base electrode 28 of each of the unit HBTs 27 also has functions as a resistance. FIG. 16B is a circuit diagram illustrating an equivalent circuit of the structure of FIG. 16A.

In the personal digital assistant of this embodiment, the base electrode 28 in each of the unit HBTs 27 in the transmission amplifier 44 functions as a ballast resistance, so that the current collapse phenomenon can be suppressed. Also, a RF input signal is input into each of the unit HBTs 27 without passing through the base electrode 28 having a high resistance. Therefore, a high gain and high efficiency can be achieved. A transmission amplifier consumes a large amount of a total current used in a personal digital assistant. In many cases, it consumes as much as 70% or more of a total current. Accordingly, the personal digital assistant of this embodiment can realize a long duration call and a long duration data communication due to the high efficiency of the transmission amplifier 44.

In this embodiment, unlike the known device, a capacitor does not have to be externally provided but can be incorporated in each of unit HBTs. Thus, a chip area can be largely reduced, so that a small-size transmission amplifier can be fabricated at low cost. Therefore, miniaturization and cost reduction of personal digital assistants can be realized.

In addition, even if a transmission amplifier is configured using one of the high-frequency semiconductor devices described in the first, second, third and fifth embodiments, or even if the high-frequency amplifier described in the fourth embodiment is used as a transmission amplifier, the same effects can be achieved.

### Other Embodiments

In each of the first through seventh embodiments, description has been made by using as example the HBT formed on the GaAs substrate. However, the present invention can be applied to, for example, an HBT including a substrate formed of some other material such as InP.

In each of the first through seventh embodiments, the case where the composition ratio of an InₓGa_{y}P film, i.e., the second emitter layer 2b is x=0.5, y=0.5 has been described. However, the composition ratio of the InₓGa_{y}P film that can be applied to the present invention is not limited thereto. Specifically, it is preferable that the composition ratio of elements in the InₓGaₓP film is 0.4≦x≦0.6, 0.4≦y≦0.6, x+y=1. It is also preferable that the InₓGa_{y}P has a thickness (t) of 10 nm≦t≦50 nm. As described in the above embodiment, a high density capacitor with no leakage current can be obtained when InₓGa_{y}P is used for the second emitter layer 2b.

In the present invention, an InP film can be used as the second emitter layer 2b. Here, it is preferable that the thickness (t) of the InP film is 10 nm≦t≦100 nm. As described in the above embodiment, a high density capacitor with no leakage current can be obtained when InP is used for the second emitter layer 2b.

In the present invention, an InₓAl_{y}As film (0.5≦x≦0.55, 0.45≦y≦0.5, x+y=1) can be used as the second emitter layer 2b. Here, it is preferable that the thickness (t) of the InₓAl_{y}As film is 10 nm≦t≦150 nm. As described in the above embodiment, a high density capacitor with no leakage current can be obtained when InₓAl_{y}As is used for the second emitter layer 2b.

In the present invention, an AlₓGa_{y}As film (0.4≦x≦0.6, 0.6≦y≦0.8, x+y=1) can be used as the second emitter layer 2b. Here, it is preferable that the thickness (t) of the AlₓGa_{y}As film is 10 nm≦t≦100 nm. As described in the above embodiment, a high density capacitor with no leakage current can be obtained when AlₓGa_{y}As is used for the second emitter layer 2b.

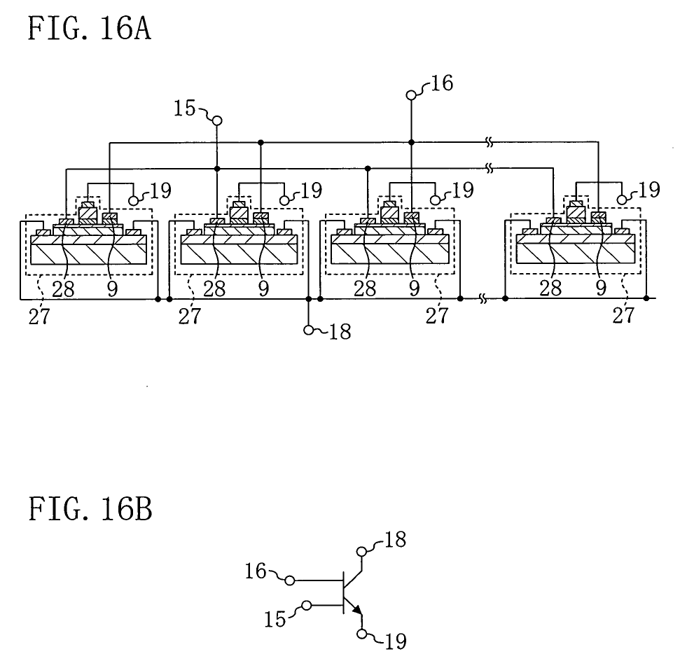

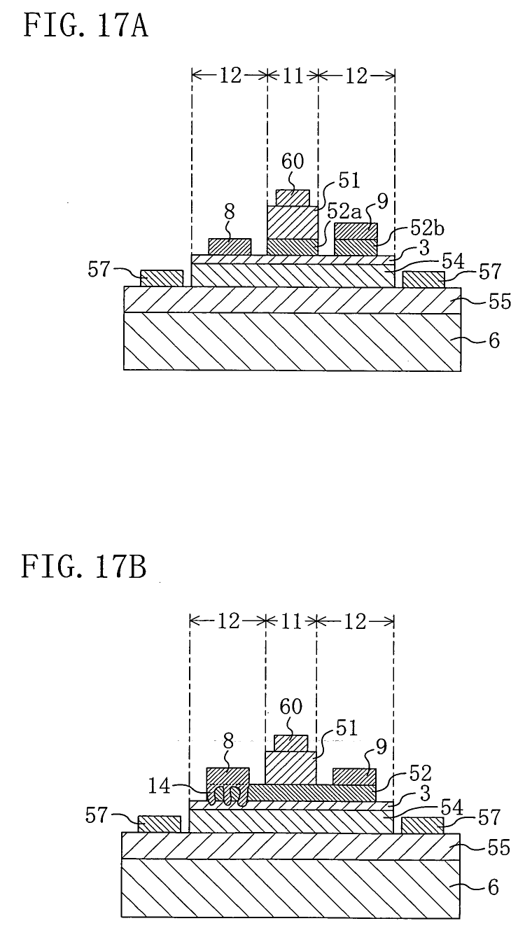

In each of the first through seventh embodiments, description has been made using as an example the emitter-up HBT in which the second emitter layer 2 (2a and 2b) and the first emitter layer 1 are provided on the base layer 3. However, the present invention can be applied to a collector-up HBT in which a collector layer is provided on a base layer. An example of the specific structure of a collector-up HBT will be described with reference to FIGS. 17A and 17B. FIG. 17A is a cross-sectional view illustrating a typical structure of a collector-up HBT according to the present invention. As shown in FIGS. 17A and 17B, in the collector-up HBT of the present invention, a sub-emitter layer 55 is formed in upper part of a GaAs substrate 6 and an emitter layer 54 and an emitter electrode 57 are formed on the sub-emitter layer 55. A base layer 3 is formed on the emitter layer 54. A second collector layer 52a is formed on part of the base layer 3 located in an intrinsic base region 11. A second collector layer 52b is formed in part of the base layer 3 located in an external base region 12. A first collector layer 51 is formed on the second collector layer 52a and a collector electrode 60 is formed on the first collector layer 51. A capacitive upper electrode 9 is formed on the second collector layer 52b.

FIG. 17B is a cross-sectional view illustrating another typical structure of the collector-up HBT of the preset invention. In the structure of FIG. 17B, a single second emitter layer 52 is formed so as to lie astride the part of the base layer 3 located in the intrinsic base region 11 and the part of the base layer 3 located in the external base region 12. A base electrode 8 is formed on the second emitter layer 52 so as to be electrically connected to the base layer 3 through an alloy region 14.

In FIGS. 17A and 17B, a modified example obtained by replacing the emitter-up HBTs described in the first embodiment with collector-up HBTs has been described. However, in the present invention, the emitter-up HBTs described in each of the second, the third, and the fifth embodiments may be replaced with collector-up HBTs. Moreover, collector-up HBTs may be used for the high-frequency amplifier of each of the fourth and sixth embodiments and the personal digital assistant of the seventh embodiment.

What is claimed is:

1. A semiconductor device comprising:
a first semiconductor layer including an intrinsic base region and an external base region;
a second semiconductor region formed on said intrinsic base region so as to serve as an emitter region or a collector region;
a capacitive film formed on part of said external base region;
an electrode provided on said capacitive film; and
a base electrode provided on other part of said external base region than the part of said external base region on which said capacitive film is provided.

2. The semiconductor device of claim 1, wherein said capacitive film is an InₓGa_{y}P film (0.4≦x≦0.6, 0.4≦y≦0.6, x+y=1).

3. The semiconductor device of claim 2, wherein said InₓGa_{y}P film has a thickness (t) of 10 nm≦t≦50 nm.

4. The semiconductor device of claim 1, wherein said capacitive film is an InP film.

5. The semiconductor device of claim 4, wherein said InP film has a thickness (t) of 10 nm≦t≦100 nm.

6. The semiconductor device of claim 1, wherein said capacitive film is an InₓAl_{y}As film (0.5≦x≦0.55, 0.45≦y≦0.5, x+y=1).

7. The semiconductor device of claim 6, wherein said InₓAl_{y}As film has a thickness (t) of 10 nm≦t≦150 nm.

8. The semiconductor device of claim 1, wherein said capacitive film is an AlₓGa_{y}As film (0.2≦x≦0.4, 0.6≦y≦0.8, x+y=1).

9. The semiconductor device of claim 8, wherein said AlₓGa_{y}As film has a thickness (t) of 10 nm≦t≦100 nm.

10. The semiconductor device of claim 1, wherein said electrode on said capacitive film is a first input terminal, and
wherein said base electrode is a second input terminal.

11. The semiconductor device of claim 1, further comprising a first connection at which said electrode and said base electrode are electrically connected with each other,
wherein said first connection is an input terminal.

12. The semiconductor device of claim 1, further comprising a resistor,
wherein one end of said resistor is connected to said base electrode and the other end of said resistor is a first input terminal.

13. The semiconductor device of claim 1, further comprising:
a resistor having one end connected to said base electrode; and
a second connection at which the other end of said resistor and said electrode are connected with each other,
wherein said second connection is an input terminal.

14. The semiconductor device of claim 1, wherein said base electrode functions as a resistor.

15. The semiconductor device of claim 1, further comprising a third semiconductor layer provided in lower part of said first semiconductor layer,
wherein said third semiconductor layer is a collector region, and
wherein said second semiconductor layer is an emitter region.

16. The semiconductor device of claim 1, further comprising a third semiconductor layer provided in lower part of said first semiconductor layer,
wherein said third semiconductor layer is an emitter region, and
wherein said second semiconductor layer is a collector region.

17. A high-frequency amplifier comprising the semiconductor device of claim 1.

18. A high-frequency amplifier comprising:
the semiconductor device of claim 1;
a DC input terminal connected to said base electrode; and
a RF input terminal connected to said electrode.

19. The high-frequency amplifier of claim 18, further comprising:
a bias circuit connected to said DC input terminal; and
an input rectifier circuit connected to said RF input terminal.

20. A personal digital assistant comprising the semiconductor device of claim 1.

21. A personal digital assistant comprising:
the semiconductor device of claim 1;
a transmission amplifier including said semiconductor device;
an antenna connected to said transmission amplifier; and
an antenna switch for switching an electrical connection between said transmission amplifier and said antenna, said antenna switch being provided between said transmission amplifier and said antenna.

22. The personal digital assistant of claim 21, wherein said transmission amplifier includes
a DC input terminal connected to said base electrode,
a RF input terminal connected to said electrode,
a bias circuit connected to said DC input terminal, and
an input rectifier circuit connected to said RF input terminal.
